(19) United States
(12) Patent Application Publication
(10) Pub. No.: US 2017/0038686 A1
(43) Pub. Date: Feb. 9, 2017

(54) ANTHRAQUINONE COMPOUND USED FOR COLOR FILTER OF LCD

(71) Applicants: Rohm and Haas Electronic Materials LLC, Marlborough, MA (US); Dow Global Technologies LLC, Midland, MI (US); Rohm and Haas Electronic Materials Korea Ltd., Cheonan (KR)

(72) Inventors: Guihong Liao, Shanghai (CN); Yang Li, Shanghai (CN); Peter Trefonas, III, Medway, MA (US); Geun Huh, Seoul (KR); Hua Ren, Shanghai (CN); Chao He, Shanghai (CN); Yu Cai, Shanghai (CN); Yanping Sun, Shanghai (CN)

(21) Appl. No.: 15/303,624

(22) PCT Filed: Apr. 18, 2014
(86) PCT No.: PCT/CN2014/075656

§ 371 Date: Oct. 12, 2016

(51) Int. Cl. G03F 7/105; C09B 1/32; G03F 7/00

(52) U.S. Cl. CPC G03F 7/105; G03F 7/0007; C09B 1/32; G02F 1/133514

(57) ABSTRACT

An anthraquinone compound which is suitable for forming a color filter used for a liquid crystal display device, a composition containing a resin and the anthraquinone compound, an article having a polymer layer formed from the composition and a color filter containing the compound are developed.

### FIELD OF THE INVENTION

The present invention relates to an anthraquinone compound which is suitable for forming a color filter used for a liquid crystal display device, a method for synthesis the anthraquinone compound, a composition containing a resin and the anthraquinone compound, an article having a polymer layer formed from the composition and a color filter comprising the anthraquinone compound.

### BACKGROUND OF THE INVENTION

Liquid crystal display (LCD) currently dominates the display market because of its excellent performance and small thickness. As a key component of LCD device, translucent color filters play the critical role of generating Red/Green/Blue lights by filtering white light from a back sheet. This capacity originates from the Red/Green/Blue colorants comprised in color filter units. Each colorant possesses a characteristic absorbance spectrum and will show one of the three primary colors when illuminated with white visible light-wavelength ranges from 380 nm to 780 nm. The controlled mixing of primary colors from each color filter unit produced by colorant will generate the final color of pixels. The efficiency of color filter directly impacts the LCD's performance

Normally, the commercialized colorants used in a LCD color filter are pigments, because they have good stability against heat, light and chemicals. Unfortunately pigments must be ground into micro/nano particles before added into a color resist to make a color filter due to their intrinsic insolubility property. When the color filter is illuminated, light scattering will take place on these particles with diameter of about 100 nm. As a result transmittance will become low, which means more light energy must be applied to provide enough brightness of the LCD.

In contrast to pigments, dyes are soluble in many materials which ensure that they can be dispersed at molecular level. If dyes are used in a color filter instead of pigments, light scattering will be significantly reduced. Thus, it could be imagined that the dye based color filter will have higher transmittance and energy cost will thus be reduced greatly. However, dye's stability against light, heat and chemical resistance is generally inferior to pigments. As a result, at present, the commercialized LCD color filters contain pigments while a few LCD contain a hybrid (or combination) of pigment and dyes.

Some anthraquinone dyes are used for color filters of a LCD. Some anthraquinone dye substituted by sulfur containing groups or halogen-containing groups has been proposed for color filters, see e.g. U.S. Pat. No. 7,615,322B, U.S. Pat No. 7,456,316B, US2008/0206658A, U.S Pat. No. 8,148,358B, JP3,651,854B and U.S. Pat. No. 5,384,377A, but those dyes generally have insufficient thermal stability or insoluble common organic solvent for a color filter.

Although the anthraquinone structure is stable, the low solubility of anthraquinone dyes in an organic solvent prevents the use of anthraquinone dyes for a color filter. Accordingly, an anthraquinone dye which is stable and satisfies the solubility in an organic solvent at the same time is still desired.

### SUMMARY OF THE INVENTION

Inventors of this invention have now found that new type of anthraquinone compound which is stable and has good solubility in an organic solvent.

Therefore, one aspect of the invention relates to an anthraquinone compound represented by the general formula (1)

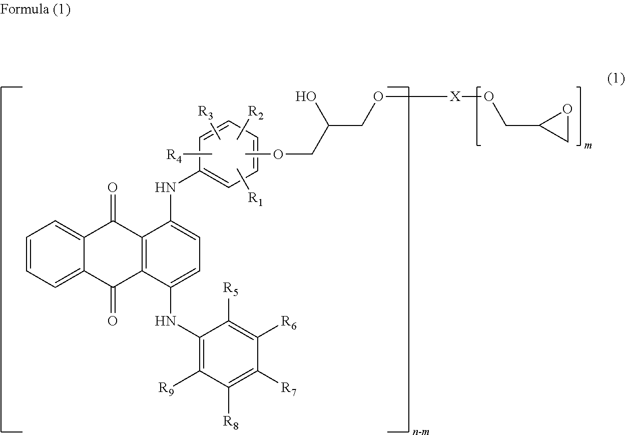

wherein R₁ to R₉ are independently selected from the group consisting of alkyl group having 1 to 20 carbon atoms, halogen atom, hydroxyl group, hydrogen atom, cyano group, sulfonyl group, sulfo group, sulfato group, silyl ether, organosilicon, deuterium atom, sulfonayl ester, nitro group, aryl group, nitro group, carboxyl group and alkoxy group having 1 to 20 carbon atoms. X is a linking group selected from aromatic, alicyclic or aliphatic groups or combination thereof. n is an integer from 2 to 6 and m is an integer from 0 to 5, but n is larger than m.

Another aspect of this invention relates to a method for synthesis the anthraquinone compound, the method comprises the step of reacting an epoxy compound with a compound represented by the following formula (2);

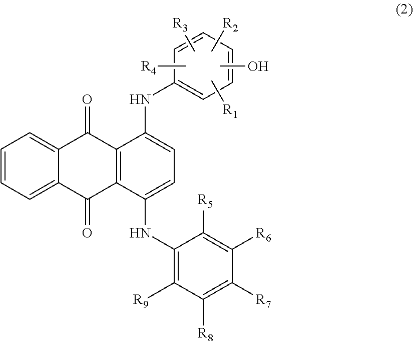

wherein R₁ to R₉ are independently selected from the group consisting of alkyl group having 1 to 20 carbon atoms, halogen atom, hydrogen atom, hydroxyl group protected by protecting group, cyano group, sulfonyl group, sulfo group, sulfato group, silyl ether, organosilicon, deuterium atom, sulfonayl ester, nitro group, aryl group, carboxyl group and alkoxy group having 1 to 20 carbon atoms.

Yet other aspects of this invention are: a composition comprising the anthraquinone compound and a resin; an article having a polymer layer formed from the composition; and a color filter comprising the anthraquinone compound.

This group of anthraquinone compounds has high enough solubility for an organic solvent used for a LCD manufacturing process, so the anthraquinone compound of this invention is useful for a color filter used in a LCD.

### DETAILED DESCRIPTION OF THE INVENTION

As used throughout this specification, the abbreviations given below have the following meanings, unless the context clearly indicates otherwise: g=gram; mg=milligram; mm=millimeter; mm=minute(s); s=second(s); hr.=hour(s); rpm=revolution per minute; ° C. =degree Centigrade. Throughout this specification, “(meth)acrylic” is used to indicate that either “acrylic” or “methacrylic” functionality may be present. As used throughout this specification, the word ‘resin’ and ‘polymer’ is used interchangeably. The word ‘alkaline soluble resin’ and ‘binder’ is used interchangeably.

<Anthraquinone Compound>

The present invention provides an anthraquinone compound represented by the general formula (1).

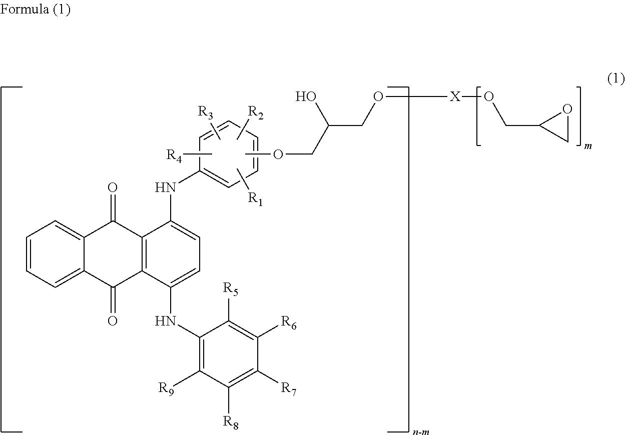

In the formula (1), R₁ to R₉ are independently selected from the group consisting of alkyl group, halogen atom, hydroxyl group, hydrogen atom, cyano group, sulfonyl group, sulfo group, sulfato group, silyl ether, organosilicon, deuterium atom, sulfonayl ester, nitro group, aryl group, nitro group, carboxyl group and alkoxy group. Preferably, R₁ to R₉ are independently selected from the group consisting of alkyl group and hydrogen atom.

The alkyl group has at least 1 carbon atom, and has less than 20 carbon atoms, preferably less than 4 carbon atoms. Examples of the alkyl group are; methyl, ethyl, propyl, butyl, hexyl, octyl, decyl, dodecyl, hexadecyl, octadecyl, isopropyl, sec-propyl, sec-butyl, tert-butyl, 2-ethylhexyl, cyclohexyl, 1-norbornyl and 1-adamantyl.

The alkoxyl group has at least 1 carbon atom, and has less than 20 carbon atoms, preferably less than 4 carbon atoms. Examples of the alkoxyl group are; methoxyl, ethoxyl, propoxyl, butoxyl, hexoxyl, octoxyl, sec-butoxyl and tert-butoxyl.

X is a linking group selected from aromatic, alicyclic or aliphatic groups or combination thereof. Those aromatic, alicyclic and aliphatic groups can contain halogen atom, nitrogen atom and oxygen atom.

As disclosed below, X is a moiety of the epoxy compound which is used to synthesize the anthraquinone compound. In the formula (1), n is an integer selected from 2 to 6 and m is an integer selected from 0 to 5, but n is always larger than m. preferably, n is 2, and preferably m is 0 or 1.

The anthraquinone compound of the present invention can be used as a mixture. For example, two or more of anthraquinone compounds which have different n and m of formula (1) compounds can be used as a mixture. Another example is a mixture of anthraquinone compounds which have different substituents as R₁ to R₉. A mixture of two or more of anturaquinone compounds can increase the solubility of the compounds in various organic solvents.

The anthraquinone compound of the formula (1) is useful in a color filter of a LCD since the anthraquinone compound of the invention has excellent thermal stability and high enough solubility for an organic solvent used in the manufacture of LCD such as propylene glycol monomethyl ether acetate (PGMEA). Without wishing to be bound to the theory, the inventors of this invention expect that the secondary hydroxyl group generated by the ring-opening of epoxy compound increases polarity of the anthraquinone compound so that the solubility in an organic solvent such as PGMEA is increased.

The anthraquinone compound of the present invention can be synthesized by the reaction of an epoxy compound with a compound represented by the following formula (2).

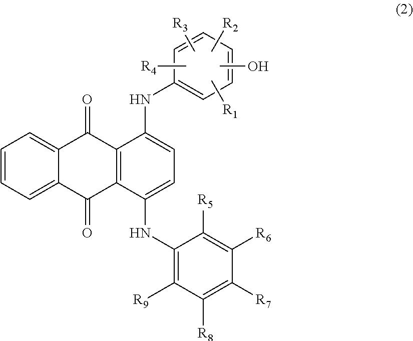

In the formula (2), R₁ to R₉ are the same as the group in the formula

The compound represented by the formula (2) can be synthesized by the following two steps. The first step is a reaction of a mixture of 2,3-dihydro-9,10-dihydroxy-1.4-anthraquinone (lecoquinzarin) and 1,4-dihydroxyanthraquinone (quinzarin) with a hydroxylaniline or derivatives thereof under the presence of at least one catalyst. Examples of the catalyst include boric acid and tryalkyl borate. An example of the reaction is disclosed below:

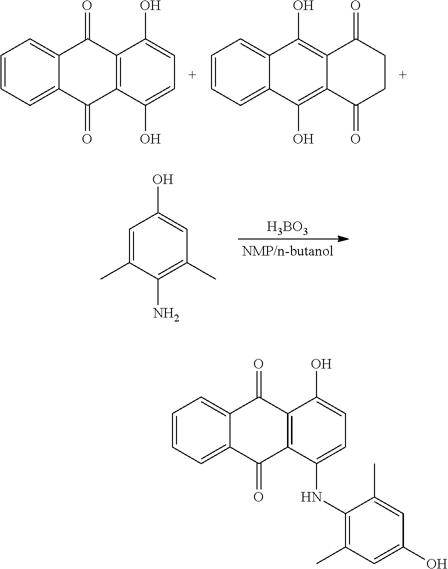

The second step is a reaction of the reaction compound of the first step with an aniline or derivatives thereof under the presence of at least one catalyst. The catalyst of the reaction is preferably boric acid. In addition, zinc powder and acid are used to help the reaction. Examples of the acid include propionic acid, pivalic acid, trifluoroacetic acid, 2,2-dimethylbutyric acid and mixtures thereof. An example of the second step is disclosed below:

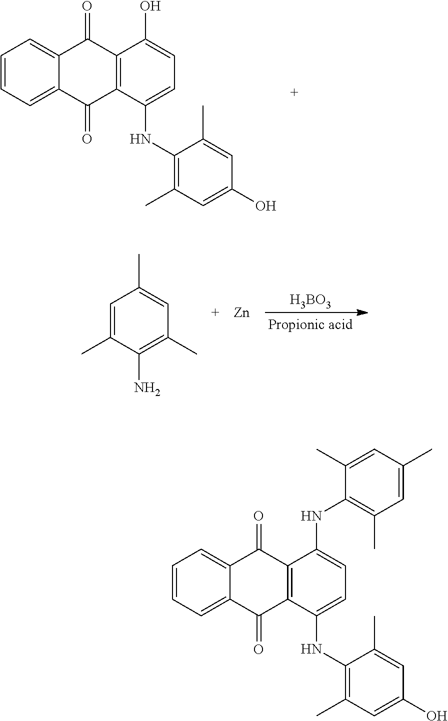

The epoxy compound used for the synthesis of the anthraquinone compound is a compound having two or more of epoxy groups.

Preferably, the epoxy compound used for the synthesis of the anthraquinone compound is represented by the following formula (3).

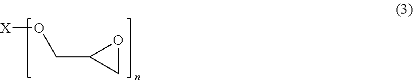

In the formula (3), X and n is the same as the formula (1).

Examples of the epoxy compounds (3) which contain aromatic group as X include glycidyl ether of polyphenols, such as hydroquinone, resorcinol, bisphenol A, bisphenol F, 4,4′-dihydroxybiphenyl, phenol novolac, cresol novolac, trisphenol (tris-(4-hydroxyphenyl)methane), 1,1,2,2-tetra(4-hydroxyphenyl)ethane, tetrabromobisphenol A, 2,2-bis(4-hydroxyphenyl)-1,1,1,3,3,3-hexafluoropropane and 1,6-dihydroxynaphthalene.

Examples of the epoxy compounds (3) which contains alicyclic group as X include polyglycidyl ethers of polyols having at least one alicyclic ring, or compounds including cyclohexene oxide or cyclopentene oxide obtained by epoxidizing compounds including a cyclohexene ring or cyclopentene ring with an oxidizer. Some particular examples include hydrogenated bisphenol A diglycidyl ether; 3,4-epoxycyclohexylmethyl-3,4-epoxycyclohexyl carboxylate;
3,4-epoxy-1-methylcyclohexyl-3,4-epoxy-1-methylhexane carboxylate;
6-methyl-3,4-epoxycyclohexylmethyl-6-methyl-3,4-epoxycyclohexane carboxylate;
3,4-epoxy-3-methylcyclohexylmethyl-3,4-epoxy-3-methylcyclohexane carboxylate;
3,4-epoxy-5-methylcyclohexylmethyl-3,4-epoxy-5-methylcyclohexane carboxylate; bis(3,4-epoxycyclohexylmethyl)adipate;
methylene-bis(3,4-epoxycyclohexane); 2,2-bis(3,4-epoxycyclohexyl)propane;
dicyclopentadiene diepoxide; ethylene-bis(3,4-epoxycyclohexane carboxylate); dioctyl epoxyhexahydrophthalate; di-2-ethylhexyl epoxyhexahydrophthalate.

Examples of the epoxy compounds (3) which contains aliphatic group as X include polyglycidyl ethers of aliphatic polyols or alkylene-oxide adducts thereof, polyglycidyl esters of aliphatic long-chain polybasic acids, homopolymers synthesized by vinyl-polymerizing glycidyl acrylate or glycidyl methacrylate, and copolymers synthesized by vinyl-polymerizing glycidyl acrylate or glycidyl methacrylate and other vinyl monomers. Some particular examples include, but are not limited to glycidyl ethers of polyols, such as 1,4-butanediol diglycidyl ether; 1,6-hexanediol diglycidyl ether; a triglycidyl ether of glycerin; a triglycidyl ether of trimethylol propane; a tetraglycidyl ether of sorbitol; a hexaglycidyl ether of dipentaerythritol.

Those epoxy compounds are commercially available or can be synthesized by the reaction of epihalohydrin with a polyol compound.

The reaction of the compound designated by the formula (2) and an epoxy compound is conducted in the presence of a base to produce an aromatic phenoxide anion at 100 to 200 degrees C. for 1 to 8 hours. A solvent which does not react with epoxy compound can be used during the reaction.

When the compound represented by the formula (2) has a hydroxyl group as R₁ to R₉ of the formula (2), the hydroxyl group has to be protected by a protecting group during the reaction of the compound represented by the formula (2) and an epoxy compound, then the protecting group is removed.

The mole ratio of the compound designated by the formula (2) with an epoxy compound is preferably 1/1 or more, more preferably 2/1 or more. The mole ratio of the compound designated by the formula (2) with an epoxy compound is preferably 6/1 or less, more preferably 3/1 or less.

When a mixture of two or more of different m or n of the formula (1), those compounds can be separated by column chromatography.

<Composition>

The composition of the present invention comprises at least one compound as recited in formula (1) and a resin. The resin is preferably alkaline soluble resin. The composition preferably additionally comprises a cross-linker (cross-linking agent), a solvent and a radiation-sensitive compound such as a photo initiator. The composition can form a film useful for a color filter.

The content of the compound as recited in formula (1) in the composition of the present invention varies depending on each molar absorption coefficient and required spectral characteristics, film thickness, or the like, but it is preferably at least 1 wt. %, more preferably at least 2 wt. %, the most preferably at least 5 wt. % based on the total solid contents of the composition. The preferable content is less than 55 wt. %, more preferably less than 45 wt. %, most preferably less than 35 wt. % based on the total solid contents of the composition.

The composition of the present invention can comprises other coloring materials in addition to the compound as recited in formula (1). Normally the use of additional coloring material is determined from the required spectral characteristics of a material to be formed from the composition.

The alkaline soluble resin is also known as ‘binder’ in this technical art. Preferably, the alkaline soluble resin is dissolved in an organic solvent. The alkaline soluble resin can be developed with an alkaline solution such as tetramethyl ammonium hydroxide aqueous solution (TMAH) after forming a film.

The alkaline soluble resin (binder) is normally a linear organic polymer. The binder optionally has a crosslinkable group within the polymer structure. When the composition of the present invention is used as a negative type photosensitive composition, such crosslinkable group can react and form crosslink by exposure or heating so that the binder becomes a polymer which is insoluble in alkaline.

Many kinds of binder are known in this art. Examples of such binder are; (meth)acrylic resin, acrylamide resin, styrenic resin, polyepoxyde, polysiloxane resin, phenolic resin, novolak resin, and co-polymer or mixture of those resins. In this application, (meth)acrylic resin (polymer) includes copolymer of (meth)acrylic acid or ester thereof and one or more of other polymerizable monomers. For example, acrylic resin can be polymerized from acrylic acid and/or acrylic ester and any other polymerizable monomers such as styrene, substituted styrene, maleic acid or glycidyl (meth)acrylate.

The binder preferably has at least 1,000 of weight-average molecular weight (Mw), more preferably at least 2,000 of Mw measured by a GPC method using polystyrene as a standard. At the same time, the binder preferably has less than 200,000 of Mw, more preferably less than 100,000 of Mw measured by the same method described above.

The amount of the binder used in the composition of the present invention is preferably at least 10 wt. %, more preferably at least 20 wt. % based on the total solid contents of the composition. At the same time, the preferable amount of the binder is less than 80 wt. %, more preferably less than 50 wt. %, the most preferably less than 30 wt. % based on the total solid contents of the composition.

The composition of this invention optionally further comprises a cross-linking agent to obtain a further hardened material. It is also known as a radical-polymerizable monomer. When the composition of this invention is used as a negative type photosensitive composition, such cross-linking agent can form a crosslink by exposure or heating and contribute to get a further hardened material. Well known cross-linking agent can be used for the composition of this invention. Examples of cross-linking agents are epoxy resin, dipentaerythritolhexaacrylate (DPHA) and substituted nitrogen containing compound such as melamine, urea, guanamine or glycol uril.

The composition of this invention optionally further comprises a solvent. The solvent to be used for the composition is not limited, but preferably selected from the solubility of components of the composition such as alkaline soluble resin or anthraquinone compound. Examples of the preferable solvent include esters such as ethylacetate, n-butyl acetate, amyl formate, butyl propionate or 3-ethoxypropionate, ethers such as diethylene glycol dimethyl ether, ethylene glycol monomethyl ether or propylene glycol ethyl ether acetate and ketones such as methylethylketone, cyclohexanone or 2-heptanone.

When the composition of this invention is a negative type radiation-sensitive composition, the composition preferably comprises a photo initiator. Photo initiator also called as photopolymerization initiator and including radical initiator, cationic initiator and anionic initiator. Examples of a photo initiator include; oxime esther type initiator, sulfonium salts initiator, iodide salts initiator and sulfonate initiator.

The composition of this invention can comprise other radiation-sensitive compound such as a radiation sensitive resin or a photo acid generator.

<Polymer Layer>

The composition of the present invention described above can form a polymer layer on an article. The polymer layer also described as ‘polymer film’ in the specification.

The content of the compound as recited in formula (1) in the polymer layer is depend on the required color of the film and the preferable content is basically the same as the content in the composition. The polymer layer also comprises an alkaline soluble resin which is disclosed above.

The polymer layer optionally comprises a photo initiator, a photo acid generator, a radiation sensitive resin and a crosslink agent disclosed above.

The method of forming the polymer layer on an article comprises the steps of; mixing the compound as recited in formula (1) with an alkaline soluble resin and solvent, coating the mixture on an article which supports a layer and heating the article to form a polymer layer (film). Optionally, the method comprises one or more of steps of exposing a layer (film) or curing a layer to form crosslinked stable layer.

The alkaline soluble resin and the solvent used to the method for forming the polymer layer are same as the one disclosed above.

Examples of an article which supports a layer (film) are glass, metal, silicon substrate and metal oxide coated material.

Any coating method can be used for the coating step, such as rotation coating, cast coating or roll coating.

The thickness of the layer (film) varies depending on the required properties of the film. The thickness of the layer is 0.1 to 5 micron, preferably 0.5 to 3 micron.

The layer (film) has high transmittance and thermal stability from the properties of the anthraquinone compound of this invention. The anthraquinone compound can be dissolved in an organic solvent, and has high thermal stability. Therefore the compound does not prevent the transmittance of a film and does not decrease the thermal stability of the film. Such property is important for a color filter of LCD. Therefore, the layer (film) of the present invention is useful as a color filter of LCD.

<Color Filter>

The color filer of this invention comprises at least one compound as recited in formula (1). The layer (film) disclosed above can be used for the color filter. Normally, a color filter has multiple units which made from colored films comprising Red/Green/Blue colorants.

The contents of the compound as recited in formula (1) in a colored film for a color filter is same as the film disclosed above, at least 1 wt. %, more preferably at least 5 wt. % based on the total weight of the colored film. At the same time, the content is less than 50 wt. %, preferably less than 35 wt. % based on the total weight of the colored film.

A film used for a color filter can be formed by the following steps; coating a solution comprising the compound as recited in formula (1), binder, a photo initiator and solvent to form a radiation sensitive composition layer on a material, exposing the layer through a patterned mask, and developing the layer with an alkaline solution. Moreover, a curing step of further heating and/or exposing the layer after developing step may be conducted as needed.

Since a color filter comprises three colored films which comprise R/G/B colorant, the steps of forming each colored film are repeated, then a color filter having such three colored films are obtained.

### EXAMPLES

### Inventive Examples 1 and 2

An anthraquinone dye (Dye 1) disclosed below was used in Inventive Example 1.

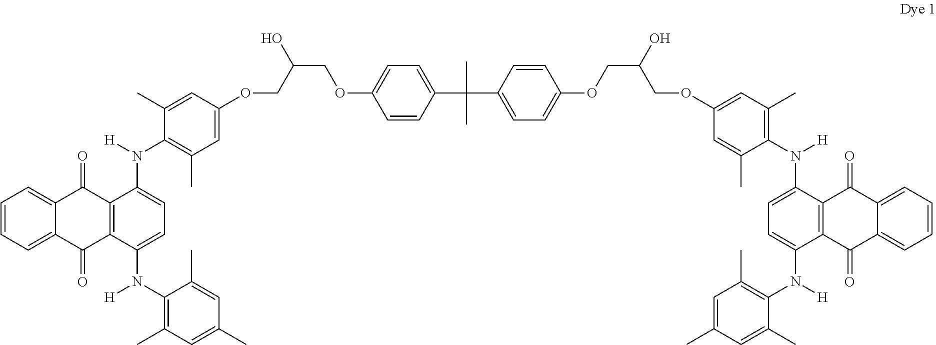 [SMILES: Cc1cc(C)c(Nc2ccc(Nc3c(C)cc(OCC(O)COc4ccc(C(C)(C)c5ccc(OCC(O)COc6cc(C)c(Nc7ccc(Nc8c(C)cc(C)cc8C)c8c7C(=O)c7ccccc7C8=O)c(C)c6)cc5)cc4)cc3C)c3c2C(=O)c2ccccc2C3=O)c(C)c1]

A mixture of the Dye 1 and another anthraquinone dye (Dye 2) disclosed below was used in Inventive Example 2.

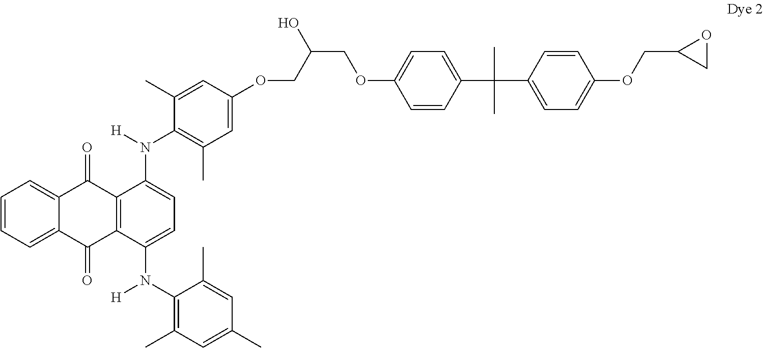 [SMILES: Cc1cc(C)c(Nc2ccc(Nc3c(C)cc(OCC(O)COc4ccc(C(C)(C)c5ccc(OCC6CO6)cc5)cc4)cc3C)c3c2C(=O)c2ccccc2C3=O)c(C)c1]

Synthesis of Mixture of Dye 1 and Dye 2

### a. Synthesis of 1-hydroxy-4-(2′, 6′-dimethyl-4′-hydroxyanilino)anthraquinone

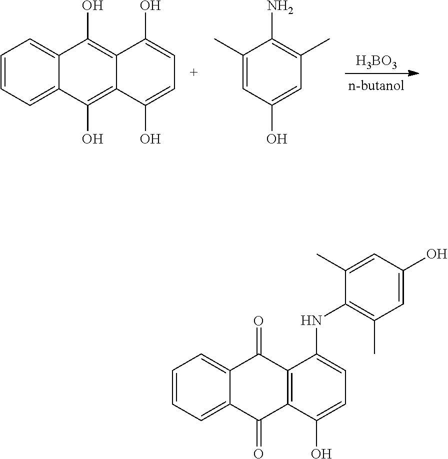

A mixture of 2.4 g (9.91 mmol) of 1,4,9.10-tetrahydroxylanthracene, 1.36 g (1 equiv.) of 2,6-dimethyl-4-hydroxylaniline, 1.0 g of boric acid and 12 mL of n-butanol was refluxed at normal pressure for 25 hours in an oil bath at 115° C. under N₂. The reaction mixture was cooled to room temperature and added thereto 1 mL 6N HCl solution while stirring. The major product was crystallized in ice-bath and filtered. The crude product was washed with water and dried. Finally the pure product was obtained by column chromatography on silica using methylene chloride as eluent. Yield: 20%. ¹H NMR (CDCl₃, ppm): 13.65 (s, 1H), 11.15 (s, 1H), 8.33 (m, 2H), 7.74 (m, 2H), 7.05 (d, 1H), 6.67 (d, 1H), 6.59 (s, 2H), 4.79 (br, 1H), 2.07 (s, 6H)

### b. Synthesis of 1-((4-hydroxy-2,6-dimethylphenyl)amino)-4-(mesitylamino)-anthraquinone

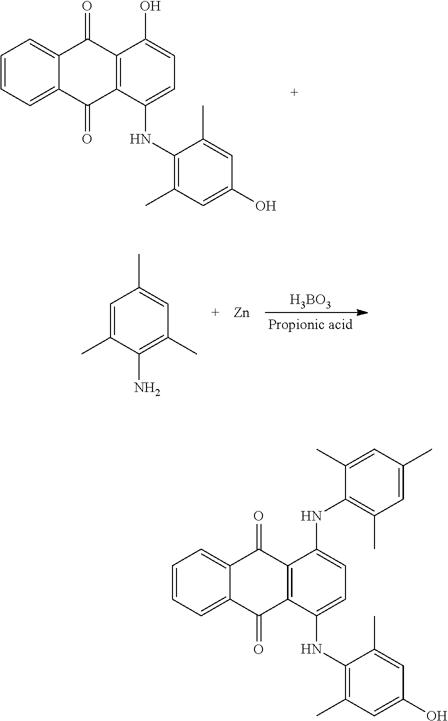

A mixture of 1.00 g of 1-hydroxy-4-(2′, 6′-dimethyl-4′-hydroxyanilino)anthraquinone, 3.76 g of trimethylaniline, 0.20 g of boric acid, 0.20 g of zinc dust, 2.0 g propionic acid was heated at 160° C. for 6 hours in an oil bath under N₂. The reaction mixture was poured into 100 mL of crushed ice containing 10 mL of concentrated hydrochloric acid. The residue remaining in the reaction flask was transferred to the ice-acid mixture using 8 mL of propionic acid. The stirred mixture was heated to 55° C. and filtered to give the mixed product. Then the crude product was washed with 5% hydrochloric acid, and water. After dried, the final product was purified by silica gel column using methylene chloride as eluent. The unsymmetrically substituted 1,4-diarylamino-anthraquinone derivative was obtained with the yield of 60%. ¹H NMR (CDCl₃, ppm): 11.74 (s, 1H), 11.60 (s, 1H), 8.35 (m, 2H), 7.69 (m, 2H), 6.86 (s, 2H), 6.54 (s, 2H), 6.50 (s, 2H), 5.22 (s, 1H), 2.22 (s, 3H), 2.07 (s, 6H), 2.02 (s, 6H). ESI-MS (m/z, Ion, Formula): 477, (M+H)⁺, C31H29N203, (theoretical mass 476)

### c. Synthesis of epoxy modified anthraquinone

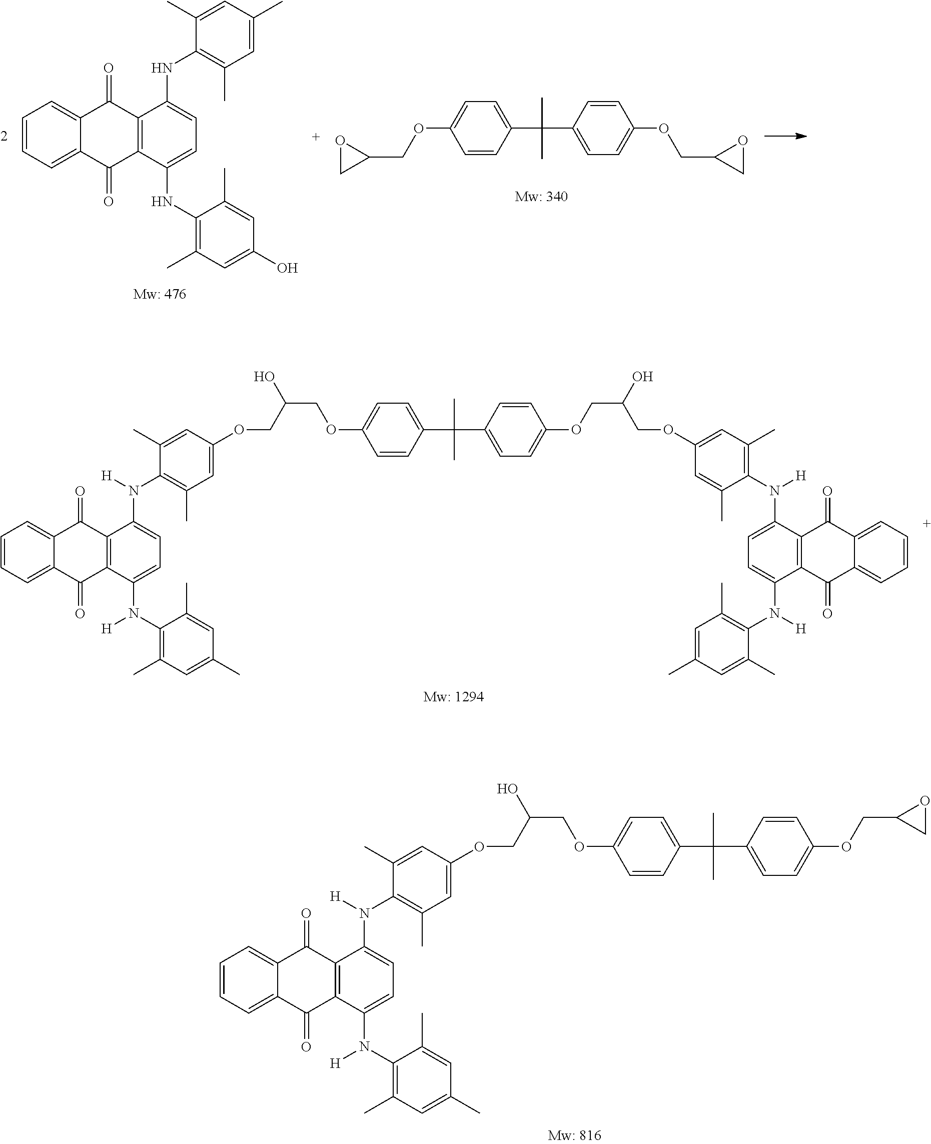 [SMILES: Cc1cc(C)c(Nc2ccc(Nc3c(C)cc(O)cc3C)c3c2C(=O)c2ccccc2C3=O)c(C)c1 ; CC(C)(c1ccc(OCC2CO2)cc1)c1ccc(OCC2CO2)cc1 ; Cc1cc(C)c(Nc2ccc(Nc3c(C)cc(OCC(O)COc4ccc(C(C)(C)c5ccc(OCC(O)COc6cc(C)c(Nc7ccc(Nc8c(C)cc(C)cc8C)c8c7C(=O)c7ccccc7C8=O)c(C)c6)cc5)cc4)cc3C)c3c2C(=O)c2ccccc2C3=O)c(C)c1 ; Cc1cc(C)c(Nc2ccc(Nc3c(C)cc(OCC(O)COc4ccc(C(C)(C)c5ccc(OCC6CO6)cc5)cc4)cc3C)c3c2C(=O)c2ccccc2C3=O)c(C)c1]

1-((4-hydroxy-2,6-dimethylphenyl)amino)-4-(mesitylamino)-anthraquinone (952mg, 2.0mmol) and bisphenol A diglycidyl ether(368mg, EEW: 184, provided by The Dow Chemical Company, Product name: DER331) were dissolved in toluene (10 mL) under nitrogen atmosphere. A catalyst (70wt. % of ethyltriphenylphosphonium acetate in methanol) 70 mg was added under stirring. The resulting mixture was stirred at 110° C. overnight. The solution was evaporated under reduced pressure. The crude product was purified by chromatography on silica and finally a mixture of epoxy modified mono-anthraquinone (Dye 2) and epoxy modified bi-anthraquinone (Dye 1) was obtained. ESI-MS (m/z, Ion, Formula): 1294, (M+H)⁺, C83H81N4010, (theoretical mass 1293); 817, (M+H)⁺, C52H53N2O7, (theoretical mass 816).

The mole ratio of Dye 1 and Dye 2 was 6:4 (measured by LC-MS). Solubility of the mixture of Dye 1 and Dye 2 in PEGMEA was about 10 wt. %.

The pure Dye 1 was separated by column chromatogaphy. ¹H NMR (CDCl₃, ppm) of Dye 1: 11.80 (s, 1H), 11.73 (s, 1H), 8.45 (m, 2H), 7.78 (m, 2H), 7.16 (d, 2H), 6.96 (s, 2H), 6.86 (d, 2H), 6.72 (s, 2H), 6.58 (d, 2H), 4.39 (m, 1H), 4.15 (m, 4H), 2.60 (d, 1H), 2.32 (s, 3H), 2.17 (s, 12H), 1.66 (s, 3H). Solubility of Dye 1 in PGMEA is 11.2wt. %. From TGA data, after baking at 230° C. for 1 hour, there is only 2wt. % loss for Dye 1.

### d. Preparation of a color resist and a color film comprising an anthraquinone dye

For Inventive Example 1, 0.15 g of Dye 1, 1.35 g of PGMEA and 1 g of alkaline soluble acrylic resin solution (MIPHOTO RPR4022, supplied from Miwan Commercial Co., Ltd., 25 to 35% of solid content in methyl 3-methoxypropionate) were mixed and stirred for 2 hours at room temperature using a shaker. For Inventive Example 2, 0.15 g of a mixture of Dye land Dye 2 was used instead of Dye 1. The solutions were filtered with a 0.45 μm PTFE filter to get rid of big particles. Then the filtered solutions were spin coated onto a clean glass substrate with 200 and 270 rpm spin speed for 18 seconds respectively. The obtained films were first dried at 90° C. under air atmosphere for 30 minutes, and then hard baked at 230° C. under air atmosphere for 1 hour. The CIE values (xyY values and lab values) and the UV-Vis were measured before and after the hard bake.

Film thickness and chromaticity coordinates of the obtained film were measured as disclosed below. Film thickness of the films were 5.2 and 2.7 micron respectively. Chromaticity coordinates measured by UltraScan Pro (Hunterlab) colorimeter were, x=0.152, y=0.140 and Y=14.46 (Inventive Example 1) and x=0.184, y=0.200 and Y=28.27 (Inventive Example 2).

The obtained dry films were further baked at 230° C. under air for 1 hour to evaluate thermal stability of the films. Optical performance after baking (AE_{ab} value) were 2.3 (Inventive Example 1) and 1.8 (Inventive Example 2), and the one of after further baking were 3.0 (Inventive Example 1) and 2.7 (Inventive Example 2). A smaller AE_{ab} value indicates better heat resistance. The results are shown in Table 1.

<Performance Evaluation>
(1) Thermal stability of dyes (Mass loss measured by TGA):
The thermal stability of dye itself was determined by the mass loss of dye measured by TGA under air atmosphere at 230° C. for 1 hour. This evaluation reflects chemical stability of the dye itself.
(2) Film thickness:
Film thickness is measured by scanning the difference in height across the boundary of film and glass substrate with atomic force microscope.
(3) Chromaticity coordinates:
The chromaticity coordinate of film on a glass sheet is directly recorded with UltraScan Pro (Hunterlab) colorimeter. The light source is D65/10.
(4) Thermal stability of films (Chromaticity):
The wet film after spin coating is dried in oven at 90° C. for 30 minutes and then soft baked at 150° C. for 15 minutes. The chromaticity coordinates (L, a, b) are recorded with UltraScan Pro (Hunterlab) colorimeter. D65/10 light source is used and results are based on CIE Lab coordinates. After that the film is hard baked at target temperature (230° C.) for 1 hour and the new chromaticity coordinates (L′, a′, b′) are recorded with the method above. The thermal stability of a film is indicated by the difference of chromaticity coordinate before and after hard baking represented by the following formula;

ΔE=\sqrt{(L−L′)²+(a−a′)²+(b−b′)²}

### Comparative Examples 1 to 3

Same procedure was conducted excepting for the dyes disclosed below were used instead of a mixture of Dye 1 and Dye 2.

### Dye used in Comparative Example 1

### 1,4-bis((isopropylamino)anthraquinone (Solvent Blue 36)

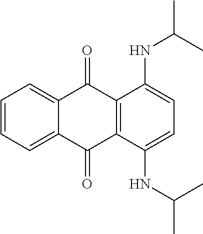 [SMILES: CC(C)Nc1ccc(NC(C)C)c2c1C(=O)c1ccccc1C2=O]

### Dye used in Comparative Example 2

### 1,4-bis(mesitylamino)anthraquinone (Solvent Blue 104)

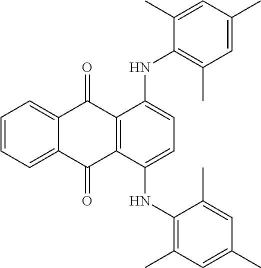 [SMILES: Cc1cc(C)c(Nc2ccc(Nc3c(C)cc(C)cc3C)c3c2C(=O)c2ccccc2C3=O)c(C)c1]

### Dye used in Comparative Example 3

(1-((4-hydroxy-2,6-dimethylphenyl)amino)-4-(mesitylamino)-anthraquinone

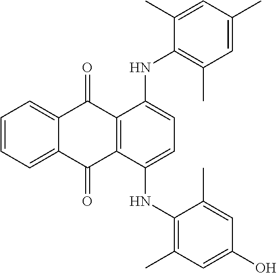 [SMILES: Cc1cc(C)c(Nc2ccc(Nc3c(C)cc(O)cc3C)c3c2C(=O)c2ccccc2C3=O)c(C)c1]

TABLE 1

| | | Solubility | ΔEab after | ΔEab after |
|---|---|---|---|---|
| | | in | baking at | baking at |
| | | PGMEA | 230° C. | 230° C. for |
| | Dyes | (wt %) | for 1 h | another 1 h |
| Inventive | Dye 1 | 11.2 | 2.3 | 3.0 |
| Example 1 | | | | |
| Inventive | A mixture of | ~10.0 | 1.8 | 2.7 |
| Example 2 | Dye 1 and Dye 2 | | | |
| Comparative | Solvent Blue 36 | 1.92 | 33 (color | Color |
| Example 1 | | | almost | disappeared |
| | | | disappeared) | |
| Comparative | Solvent Blue 104 | 0.6 | 7.9 | 6.1 |
| Example 2 | | | | |
| Comparative | (1-((4-hydroxy- | 2.8 | 6.8 | 6.0 |
| Example 3 | 2,6-dimethyl- | | | |
| | phenyl)amino)- | | | |
| | 4-(mesitylamino)- | | | |
| | anthraquinone_{—} | | | |

Referring to Table 1, it can be found that Examples 1 and 2 show significant improvement in both thermal stability and solubility in PEGMEA compare with the Comparative Examples.

### Inventive Example 3

| | Solid | Dye/pigment: |
|---|---|---|
| | content | weight ratio 8/2 |
| MIPHOTO RPR4022 | 31.43 | 22.2 |
| DPHA (crosslinker) | 80 | 8.7 |
| PGMEA | | 34.7 |
| OXE-01 (photoinitiator) | | 0.4 |
| Blue pigment Millbase | 19.11 | 24.7 |
| (pigment content: 13 wt %) | | |
| Dye solution | 10 | 8.0 |
| leveling agent | 10 | 0.6 |
| Adhesion promotor | 10 | 0.6 |

A mixture of Dye 1 and a pigment (commercially available blue pigment mill base: product name is C.I. blue pigment 15:6) was used as a colorant. The weight ratio of the pigment/Dye 1 was 8/2. The color resist (solution) was obtained according to the above composition. The solution was spin coated onto a clean glass substrate with 200, 300 and 400 rpm spin speed respectively. The obtained films were first dried at 90 ° C. under air atmosphere for 100 seconds. The obtained film was exposed to the light of 365 nm in an exposure amount of 100 mJ/cm². Finally, the film was further cured at 230° C. under air atmosphere for 30 minutes. The CIE values (xyY values) were measured using MCPD-6000 (otsuka electronics, Japan) and C2 as light source.

TABLE 2

| | | | Film | | | |
|---|---|---|---|---|---|---|
| | | coating | thickness | | | |
| | composition | rpm | (μm) | Y | x | y |
| Inventive | P/D = 8/2 | 200 | 3.71 | 11.73 | 0.134 | 0.107 |
| Example 3 | | 300 | 2.42 | 16.82 | 0.136 | 0.132 |
| | | 400 | 1.82 | 21.30 | 0.141 | 0.153 |

Thermal stability of the films was measured. After the exposure step, the films were heated at 230° C. for 2 hours. The L, a, b values were tested every 30 minutes. AE was calculated same as Inventive Example 1.

TABLE 3

ΔEab

| | 30 min | 60 min | 90 min | 120 min |
|---|---|---|---|---|
| Inventive Example 3 | 0.38 | 0.85 | 2.34 | 2.30 |

Light stability of the films was measured. The films after the exposure and further cured at 230° C. for 30min were exposed to the light of 365 nm in an exposure amount of 5J/cm² for 3 times and the L, a, b values were tested every time.

TABLE 4

| | ΔEab | | |
|---|---|---|---|
| | 1step | 2step | 3step |
| Inventive Example 3 | 1.03 | 0.40 | 0.12 |

Chemical resistance of the films was measured. The films after the exposure and further cured at 230° C. were dipped into NMP (N-methyl-pyrrolidone) at 60° C. for 10min and the L, a, b values were tested before and after the treatment.

TABLE 5

| | ΔEab |
|---|---|
| Inventive Example 3 | 0.17 |

What is claimed is:

1. A compound represented by the following formula (1), 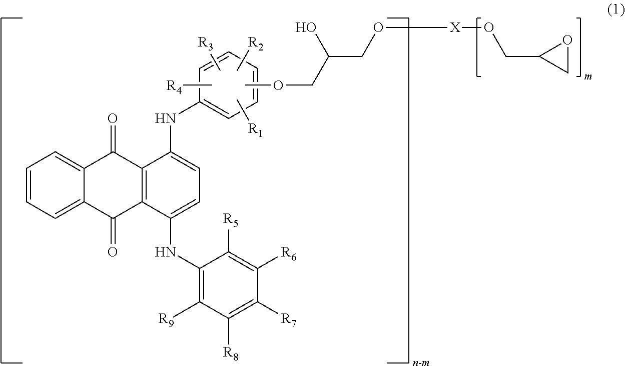
wherein R₁ to R₉ are independently selected from the group consisting of alkyl group having 1 to 20 carbon atoms, halogen atom, hydroxyl group, hydrogen atom, cyano group, sulfonyl group, sulfo group, sulfato group, silyl ether, organosilicon, deuterium atom, sulfonyl ester, nitro group, aryl group, nitro group, carboxyl group and alkoxy group having 1 to 20 carbon atoms; X is a linking group selected from aromatic, alicyclic or aliphatic groups or combination thereof; n is an integer from 2 to 6; m is an integer from 0 to 5; n is larger than m.

2. The compound of claim 1, wherein n is 2.

3. The compound of claim 1 or 2, wherein R₁ to R₉ are independently selected from the group consisting of hydrogen atom or alkyl group having 1 to 8 carbon atoms.

4. A method for synthesis the compound of claim 1, wherein the method comprises reacting an epoxy compound with a compound represented by the following formula (2); 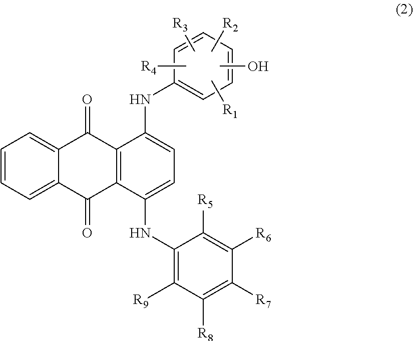
wherein R₁ to R₉ are independently selected from the group consisting of alkyl group having 1 to 20 carbon atoms, halogen atom, hydrogen atom, hydroxyl group protected by protecting group, cyano group, sulfonyl group, sulfo group, sulfato group, silyl ether, organosilicon, deuterium atom, sulfonayl ester, nitro group, aryl group, carboxyl group and alkoxy group having 1 to 20 carbon atoms.

5. The method of claim 4, wherein the epoxy compound is represented by the following formula (3); 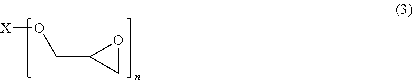
wherein X is a linking group selected from aromatic, alicyclic or aliphatic groups or combination thereof; n is an integer from 2 to 6.

6. The method of claim 4, wherein the mole ratio of the compound (2) with the epoxy compound is from 2/1 to 6/1.

7. The method of any of claims 4 to 6, wherein the epoxy compound is a reaction compound of epihalohydrin with a bisphenol or diol compound selected from the group consisting of bisphenol A, bisphenol F, 1,4-butanediol and 1,6-butanediol.

8. A composition comprising the compound of any of claims 1 to 3 and a resin.

9. The composition of claim 8, further comprising at least one pigment.

10. The composition of claim 8 or 9 further comprising a radiation-sensitive compound.

11. The composition of any of claims 8 to 10 further comprising a solvent.

12. An article having a polymer layer formed from the composition of any of claims 8 to 11.

13. The article of claim 12 wherein the polymer layer is formed from a negative-type film.

14. A color filter comprising the compound of any of claims 1 to 3.

15. The color filter of claim 14, further comprising at least one pigment.
